(19) United States
(12) Patent Application Publication
(10) Pub. No.: US 2010/0044846 A1
(43) Pub. Date: Feb. 25, 2010

(54) THREE-DIMENSIONAL STRUCTURAL SEMICONDUCTOR DEVICE

(75) Inventors: Tadahiro Ohmi, Miyagi (JP); Msahiro Konda, Miyagi (JP)

Correspondence Address: FOLEY AND LARDNER LLP;SUITE 500, 3000 K STREET NW, WASHINGTON, DC, 20007, US

(73) Assignee: National University Corporation Tohoku University

(21) Appl. No.: 12/450,441

(22) PCT Filed: Mar. 28, 2008
(86) PCT No.: PCT/JP2008/056018

§ 371 Date: Sep. 25, 2009

(30) Foreign Application Priority Data
Mar. 29, 2007 (JP) 2007-088444

(51) Int. Cl. H01L 27/06; H01L 21/70

(52) U.S. Cl. 257/686; 438/109; 257/E27.026; 438/667; 257/776; 257/E21.532

(57) ABSTRACT

A semiconductor device of three-dimensional structure in which the operating frequency of a chip can be raised while preventing the chip area from increasing. The three-dimensional structure semiconductor device have a first integrated circuit including a plurality of areas formed on a first conductor layer and a first wiring layer formed on the first conductor layer, a first insulating layer laminated on the first wiring layer, and a second integrated circuit including a plurality of areas formed on a second conductor layer which is laminated on the first insulating layer, and a second wiring layer formed on the second conductor layer. The first integrated circuit and the second integrated circuit are connected electrically by interconnection penetrating in the laminating direction and at least one of bidirectional communication of data, control signal supply, and clock signal supply between the first integrated circuit and the second integrated circuit is carried out through the penetrating interconnection.

### TECHNICAL FIELD

The present invention relates to a semiconductor device widely used for an IC, an LSI and the like, and particularly, the present invention relates to a three-dimensional structural semiconductor device.

### BACKGROUND ART

Currently, a two-dimensional structural semiconductor device is mounted as an LSI on every device and every apparatus such as a computer, a cellular phone, home electronics, and an automobile, and it becomes absolutely necessary to our lives. However, in recent years, a size of an integrated circuit becomes large particularly, and a high-speed operation of the integrated circuit becomes difficult due to increase in a wiring length and increase in load capacitance. Thus, research and development of a three-dimensional structural semiconductor device have been carried out actively. By laminating two-dimensional integrated circuits to become three-dimensional, the three-dimensional structural semiconductor device has been made to aim for (1) high integration and high density due to the number of layers, (2) a high-speed operation due to reduction of a wiring length and reduction of load capacitance, (3) propagation of synchronization signals (parallel signal processing) between layers via a number of minute through holes, and (4) integration of heterogeneous devices (multi-functionalization). Then, as a method of achieving this three-dimensional structural semiconductor device, a method of laminating two-dimensional integrated circuits as multilayer, a method of making a three-dimensional structure by applying a plurality of devices, and the like may be mentioned. It is assumed that a size of each IP in a system LSI on which a CPU, a memory, a dedicated logic and various interfaces are mounted becomes large from now on, and realization of these three-dimensional structural semiconductor devices has been expected.

### DISCLOSURE OF THE INVENTION

Problems to be solved by the Invention

In a system LSI, transmission and reception of data among a CPU, a memory, a dedicated logic and various interfaces are normally carried out via a data bus. A data bus length in a normal two-dimensional structural integrated circuit amounts to a length substantially corresponding to a chip size, and a buffer circuit for speed up is normally embedded therein. As described above, research and development of the three-dimensional structural semiconductor device are carried out to aim for high-speed operations due to reduction of a wiring length and reduction of load capacitance. However, in the case of building three-dimensionally by a technique to stick two-dimensional integrated circuits manufactured with current arrangement architecture of each IP together, a data bus length becomes (a data bus length per one layer)×(the number of laminated layers). Thus, the wiring length may increase adversely, and this becomes a problem. When the wiring length increases, it becomes difficult to heighten an operating frequency of a chip. In order to solve this problem, it is required to insert a large number of transistors, so-called repeaters, and as a result, there is a problem that a chip area increases.

It is therefore an object of this invention to provide a three-dimensional structural semiconductor device capable of preventing an area of a chip in a two-dimensional sense from increasing and of heightening an operating frequency of a chip.

### Means to Solve the Problem

According to the invention, there is obtained a three-dimensional structural semiconductor device, which comprises: a first integrated circuit constructed so as to include a plurality of regions formed in a first semiconductor layer and a first wiring layer formed on the first semiconductor layer; a first insulating layer laminated on the first wiring layer; and a second integrated circuit constructed so as to include a plurality of regions formed in a second semiconductor layer laminated on the first insulating layer and a second wiring layer formed on the second semiconductor layer, wherein the first integrated circuit and the second integrated circuit are electrically connected by means of wiring penetrating in a laminated direction.

Preferably, at least one of two-way data communication between the first integrated circuit and the second integrated circuit, supply of a control signal and supply of a clock signal is carried out via the penetrating wiring.

The three-dimensional structural semiconductor device may have a configuration in which one or more layered structure in which an insulating layer, a semiconductor layer and a wiring layer are laminated on the second wiring layer in this order is formed; an integrated circuit including a plurality of regions formed in the semiconductor layer of the layered structure and a wiring layer of the layered structure is configured; the penetration wiring penetrates the semiconductor layer and the wiring layer of the layered structure in the laminated direction to be electrically connected to the integrated circuit in each group; and at least one of two-way data communication, control signal communication, and supply of a clock signal among the first integrated circuit, the second integrated circuit, and the integrated circuit of the layered structure is carried out via the penetration wiring.

The first wiring layer and the second wiring layer is preferred to include a multilayer wiring layer.

The regions formed on the semiconductor layers include a source region, a drain region and a channel region of an insulated gate transistor.

Any of the two-way data communication, the control signal communication, and the supply of a clock signal may be adapted to be carried out via the penetrating wiring.

The penetration wiring may be arranged in a central portion or an edge portion of the first semiconductor layer.

A buffer circuit may be inserted on the way of the penetration wiring.

In a preferable form, each of the first integrated circuit and the second integrated circuit includes one or more specific circuit.

The penetration wiring is electrically connected to each of the specific circuits via a bus interface.

The specific circuit is constructed from any one of a CPU, a memory, a dedicated hard logic and an external interface.

Each of the first integrated circuit and the second integrated circuit is constructed from at least one of a digital circuit, an analog circuit, and a digital-analog mixed circuit.

In addition to the penetration wiring, the first wiring layer and the second wiring layer may be connected by means of local bus wiring for carrying out two-way local data communication between the first integrated circuit and the second integrated circuit.

Preferably, the penetration wiring is formed from at least one of materials composed of metallic materials and carbon.

Preferably, the first insulating layer is formed from at least one of an oxide, a nitride and a carbon compound whose dielectric constant is less than five.

Preferably, the first insulating layer may be formed from at least one of CFx (x<4), CHx and a porous material whose dielectric constant is 2.5 or less.

In accordance with the present invention, there is obtained a method of manufacturing a three-dimensional structural semiconductor device. The method comprises forming a first integrated circuit constructed so as to include a plurality of regions formed in a first semiconductor layer and a first wiring layer formed on the first semiconductor layer; forming a second integrated circuit constructed so as to include a plurality of regions formed on a second semiconductor layer laminated on a first insulating layer laminated on the first wiring layer, and a second wiring layer formed on the second semiconductor layer; forming penetration wiring that penetrates the first semiconductor layer and the second semiconductor layer in a laminated direction; and electrically connecting the first integrated circuit to the second integrated circuit by means of the penetration wiring.

According to the present invention, the configuration described above allows a data bus length used in a system LSI and the like to be shortened compared with the case of a two-dimensional structure, and to provide the shortest data bus length even in the case of a three-dimensional structure. As a result, the configuration according to the present invention effectively provides a semiconductor device that can operate even at 50 GHz, for example, although it was difficult to propagate a signal with 1 GHz in a two-dimensional structure without a repeater or the like.

### BRIEF DESCRIPTION OF THE DRAWINGS

FIG. 1 is a view of a basic sectional structure of a three-dimensional structural semiconductor device according to a first embodiment of the present invention in which a data bus that is a component of a system LSI is formed as penetration wiring and arranged at the center of a chip of the system LSI;

FIG. 2 is a view showing a sectional structure of the three-dimensional structural semiconductor device when viewed from an upper portion of lamination in regard to the first embodiment of the present invention, which schematically shows a configuration in which the data bus formed as the penetration wiring is connected to each IP;

FIG. 3 is a view showing a sectional structure of the three-dimensional structural semiconductor device when viewed from the upper portion of the lamination in regard to the first embodiment of the present invention, which schematically shows a configuration in which the data bus formed as the penetration wiring is connected via a data bus interface (I/F) of each IP;

FIG. 4 is a view showing a sectional structure of the three-dimensional structural semiconductor device in regard to the first embodiment of the present invention in which a kind and an arranging method of the IPs arranged on each semiconductor layer are schematically shown;

FIG. 5 is a view showing a second embodiment of the present invention, which shows a basic structure of a three-dimensional structural semiconductor device in which data bus penetration wiring is arranged at an edge of a chip of a system LSI;

FIG. 6 is a view showing a sectional structure of the three-dimensional structural semiconductor device in regard to the second embodiment of the present invention in which a kind and an arranging method of the IPs arranged on each semiconductor layer are schematically shown;

FIG. 7 is a view for explaining a formation process of a first layer of two-dimensional LSI in the three-dimensional structural semiconductor device in regard to the first embodiment of the present invention;

FIG. 8 is a view for explaining a formation process of a second layer of two-dimensional LSI in the three-dimensional structural semiconductor device in regard to the first embodiment of the present invention;

FIG. 9 is a view for explaining a formation process of a third layer of two-dimensional LSI in the three-dimensional structural semiconductor device in regard to the first embodiment of the present invention;

FIG. 10 is a chart showing propagation simulation of clock signals in data bus wiring of a conventional two-dimensional LSI; and

FIG. 11 is a chart showing propagation simulation of clock signals in data bus wiring of the three-dimensional structural semiconductor device according to the present invention.

### BEST MODE FOR CARRYING OUT THE INVENTION

Hereinafter, embodiments of this invention will be described with reference to the drawings.

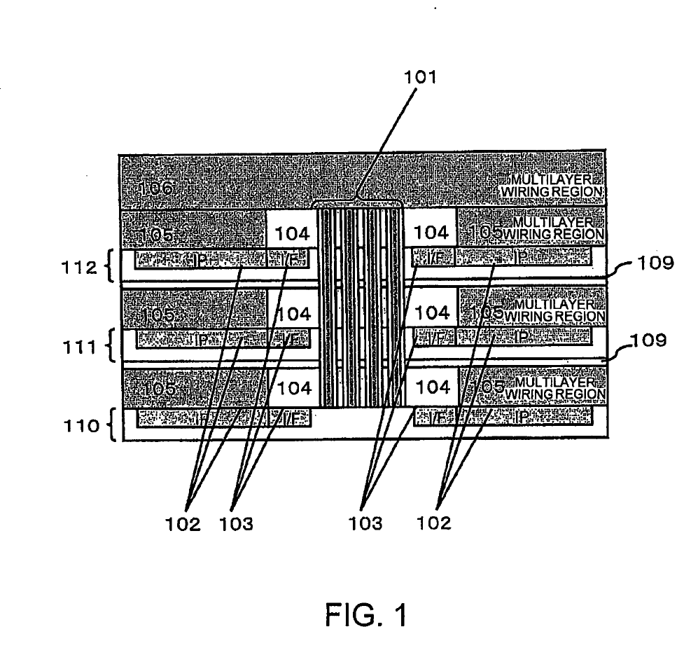

FIG. 1 is a sectional view showing a semiconductor device according to a first embodiment of the present invention, and shows a basic structure of a three-dimensional structural semiconductor device in which a data bus that is a component of a system LSI is formed as penetration wiring and data bus penetration wiring thereof is arranged at the center of a chip of the system LSI.

As shown in FIG. 1, a wiring circumference of data bus penetration wiring (101) is covered with an insulating film, and the data bus penetration wiring (101) penetrates through a first semiconductor layer (110), a second semiconductor layer (111) and a third semiconductor layer (112). IPs (Intellectual Properties), that is, “specific circuits” (102) formed on each of the semiconductor layers are connected to desired data bus penetration wiring (101) via a data bus interface (I/F, 103) of each IP and multilayer wiring regions for connection of data buses (104). The IPs arranged in each semiconductor layer mean a microprocessor unit, a memory, a dedicated logic, various external interface circuits and the like here. However, even though IPs other than these are arranged, it has no influence on the effect of the present invention.

Further, a multilayer wiring region (105) is internal wiring for constructing each IP (102). Wiring for connecting to the nearest IP (102) is also arranged in the multilayer wiring region (105) if necessary.

In this regard, in this embodiment, three multilayer structures each constructed from the semiconductor layer (110, 111 or 112) and the multilayer wiring layers (the layers including 104 and 105) are laminated via an insulating layer 109, and the penetration wiring (101) penetrate these multilayer structures and insulating layers.

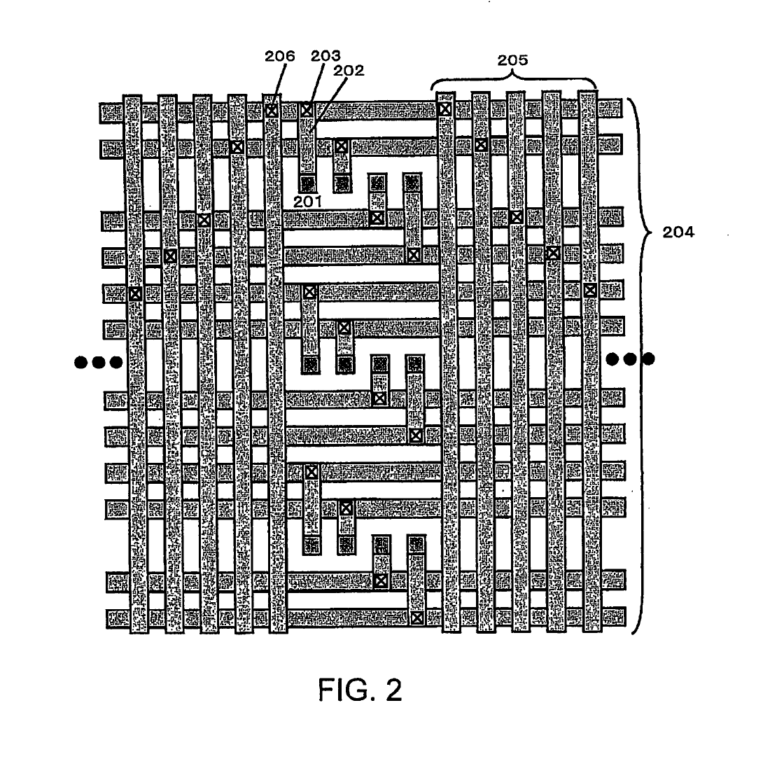

FIG. 2 is a sectional structure of the three-dimensional structural semiconductor device when viewed from an upper portion of lamination in regard to the first embodiment of the present invention, which schematically shows a configuration in which the data bus formed as the penetration wiring is connected to each IP (102).

As shown in FIG. 2, data bus penetration wiring (201) is connected to lateral data bus lines (204) via wiring (202) in the multilayer wiring regions for connection of data buses (104) and contact holes (203). Moreover, they are connected to the data bus interfaces (103) of each IP (102) via contact holes (206) and wiring (205) from the lateral data bus lines (204). In this regard, the wiring (204, 205) for developing the data bus penetration wiring (201) in a longitudinal direction on a plane and the contacts (203, 206) lie in the multilayer wiring region for connection of data buses (104), and are connected to the data bus interfaces (103) of each IP. A method of connecting wiring herein is one example. So long as the data bus penetration wiring can be connected to the data bus interfaces of each IP, other connecting method has no influence on the present invention.

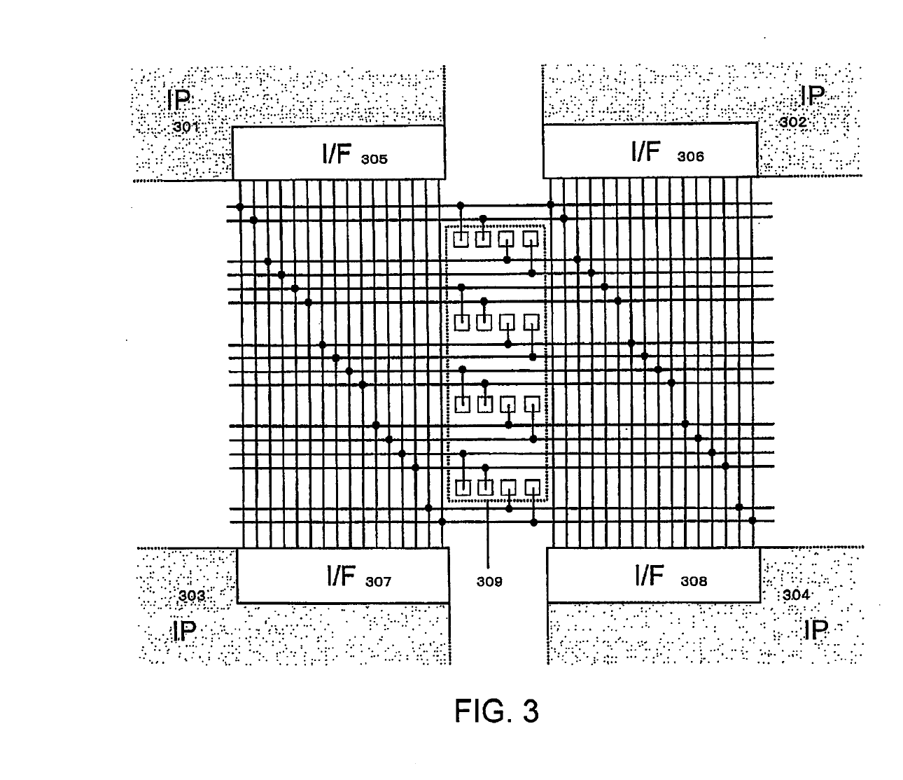

FIG. 3 is sectional information of the three-dimensional structural semiconductor device when viewed from the upper portion of the lamination in regard to the first embodiment of the present invention, which schematically shows a configuration in which the data bus formed as the penetration wiring is connected via a data bus interface (I/F) of each IP.

As shown in FIG. 3, IPs (301, 302, 303 and 304) formed in each semiconductor layer are connected to data bus penetration wiring (309) via data bus interfaces (305, 306, 307 and 308), respectively. A method of connecting via the data bus interfaces (305, 306, 307 and 308) herein is one example. Even though the data bus penetration wiring (309) and each of the IPs (301, 302, 303 and 304) are connected without the data bus interface in order to satisfy desired functions, it has no influence on the present invention.

Further, in FIG. 3, the IPs formed in one semiconductor layer are four kinds, and each of the IPs is connected to the data bus penetration wiring via the data bus interface. However, this is one example. Even though the IPs formed in one semiconductor layer are one IP or a plurality of IPs, it has no influence on the present invention.

Further, although the data bus penetration wiring (309) is constructed from 16 pieces of wiring, this is one example of the first embodiment, and there is no limitation in the number of wiring.

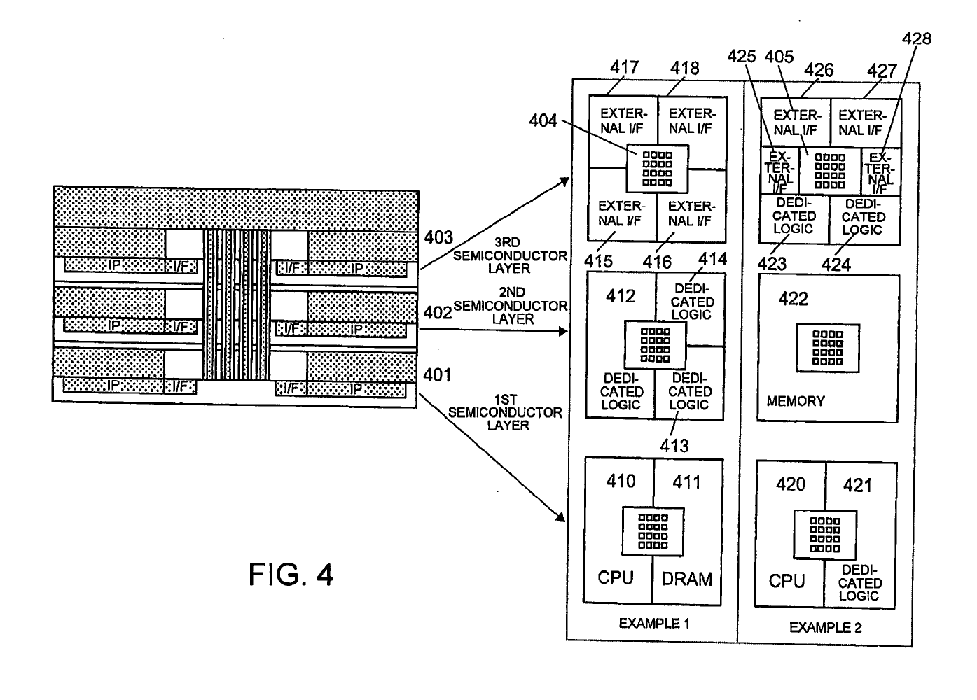

FIG. 4 is a sectional structure of the three-dimensional structural semiconductor device in the first embodiment of the present invention in which a kind and an arranging method of the IPs arranged on each semiconductor layer are schematically shown.

As shown in FIG. 4, the respective IPs formed in a first semiconductor layer (401), a second semiconductor layer (402) and a third semiconductor layer (403) are indicated as Example 1 (410 to 418) and Example 2 (420 to 426), and explanation will be made with two kinds of examples.

As shown in Example 1 of FIG. 4, a CPU (410) and a DRAM (411) are arranged in the first semiconductor layer (401) as IPs to be connected to data bus penetration wiring (404). Next, dedicated logics (412, 413 and 414) are arranged in the second semiconductor layer (402) as IPs to be connected to the data bus penetration wiring (404). The dedicated logics herein are IPs for satisfying desired functions of the three-dimensional semiconductor device, such as an image processing processor. If they perform the desired functions, they have no influence on the present invention. Next, external I/Fs (415, 416, 417 and 418) that play a role in an interface with the outside such as other LSI are arranged in the third semiconductor layer (403) as IPs to be connected to the data bus penetration wiring (404). So long as the external I/Fs herein are interfaces for satisfying desired functions of the three-dimensional semiconductor device, such as a USB interface and an IEEE1394 interface, they have no influence on the present invention.

As shown in Example 2 of FIG. 4, a CPU (420) and a dedicated logic (421) are arranged in the first semiconductor layer (401) as IPs to be connected to the data bus penetration wiring (405). Next, a memory (422) is arranged in the second semiconductor layer (402) as an IP to be connected to the data bus penetration wiring (405). So long as the memory herein has a memory function such as an SRAM, a DRAM and a FeRAM, it has no influence on the present invention even though any is arranged as the IP. Next, external I/Fs (425, 426, 427 and 428) that play a role in an interface with the outside such as other LSI are arranged in the third semiconductor layer (403) to be connected to the data bus penetration wiring (405). Further, dedicated logics (423, 424) are arranged as IPs to be connected to the data bus penetration wiring (405). So long as the external I/Fs herein are interfaces for satisfying desired functions of the three-dimensional semiconductor device, such as a USB interface and an IEEE1394 interface, they have no influence on the present invention. Moreover, the dedicated logics herein are IPs for satisfying desired functions of the three-dimensional semiconductor device, such as an image processing processor. If they are the desired functions, they have no influence on the present invention.

Further, in FIG. 4, the three-dimensional semiconductor device composed of three layers of semiconductor layers including the first semiconductor layer (401), the second semiconductor layer (402) and the third semiconductor layer (403) has been mentioned as an example. However, so long as the number of layers to be laminated are the number necessary for realizing the function, it has no influence on the present invention].

Moreover, the configuration in which 1, 2, 3, 4 or 6 pieces of IPs per one layer are arranged has been mentioned as an example with respect to the number of IPs connected to the data bus penetration wiring per one layer. However, so long as the number necessary for realizing the function is arranged, it has no influence on the present invention.

The data bus penetration wiring is connected to the IPs formed in each of the semiconductor layers to serve as a common data bus of the whole system LSI, but data bus wiring may be arranged locally in addition to this data bus penetration wiring. The local data bus wiring is connected to the wiring layer for each IP formed in each semiconductor layer. This can serve as two-way communication between the respective IPs.

Next, a second embodiment of this invention will be described with reference to the drawings.

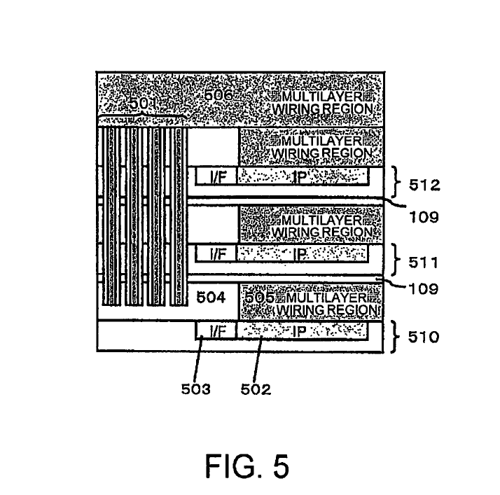

FIG. 5 is a sectional view showing a semiconductor device according to a second embodiment of the present invention, and shows a basic structure of a three-dimensional structural semiconductor device in which a data bus that is a component of a system LSI is formed as penetration wiring and is arranged at an edge of a chip of the system LSI.

As shown in FIG. 5, a wiring circumference of data bus penetration wiring (501) is covered with an insulating film, and the data bus penetration wiring penetrates a first semiconductor layer (510), a second semiconductor layer (511) and a third semiconductor layer (512). An IP (502) formed in each semiconductor layer is connected to the desired data bus penetration wiring (501) via a data bus interface (I/F, 503) and a multilayer wiring region for connection of data buses (504) of each IP. The IP arranged in each semiconductor layer herein means a microprocessor unit (CPU), a memory, a dedicated logic, various external interface circuits and the like. However, even though IPs other than this are arranged, it has no influence on the effect of the present invention.

Further, a multilayer wiring region (505) is internal wiring for constructing each IP (502). Wiring for connecting to the nearest IP (502) is also arranged in the multilayer wiring region (505) if necessary.

In this regard, in this embodiment, three multilayer structures each constructed from the semiconductor layer (510, 511 or 512), the multilayer wiring layers (the layers including 504 and 505) are laminated via an insulating layer (109), and the penetration wiring (501) penetrates these multilayer structures and insulating layers.

Moreover, although the data bus penetration wiring (501) is formed at a left edge of the three-dimensional structural semiconductor device in FIG. 5, this is just one example. Wherever it is arranged, it has no influence on the effect of the present invention so long as it satisfies the function.

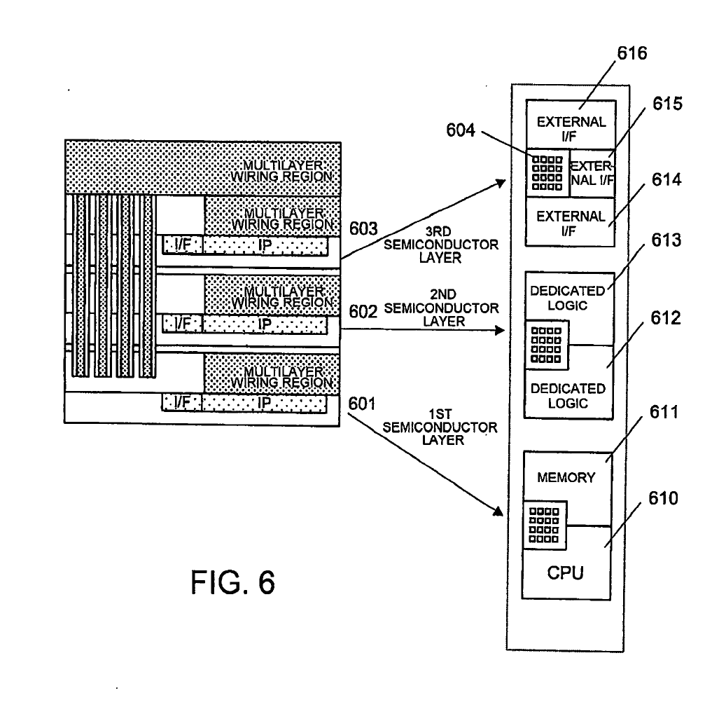

FIG. 6 is a sectional structure of the three-dimensional structural semiconductor device in the second embodiment in which a kind and an arranging method of the IPs arranged on each semiconductor layer are schematically shown.

As shown in FIG. 6, the respective IPs formed in a first semiconductor layer (601), a second semiconductor layer (602) and a third semiconductor layer (603) are indicated as 610 to 616, and explanation will be made.

As shown in FIG. 6, a CPU (610) and a memory (611) are arranged in the first semiconductor layer (601) as IPs to be connected to data bus penetration wiring (604). Next, dedicated logics (612, 613) are arranged in the second semiconductor layer (602) as IPs to be connected to the data bus penetration wiring (604). Next, external I/Fs (614, 615 and 616) that play a role in an interface with the outside such as other LSI are arranged in the third semiconductor layer (603) as IPs to be connected to the data bus penetration wiring (604).

The dedicated logics (612, 613) herein are IPs for satisfying desired functions of the three-dimensional semiconductor device, such as an image processing processor. If they are the desired functions, they have no influence on the present invention.

Further, so long as the external I/Fs (614, 615 and 616) herein are interfaces for satisfying desired functions of the three-dimensional semiconductor device, such as a USB interface and an IEEE1394 interface, they have no influence on the present invention.

Although the number of IPs arranged in each semiconductor layer is two or three here, it goes without saying that there is no limitation on the number to satisfy the desired functions of the three-dimensional semiconductor device.

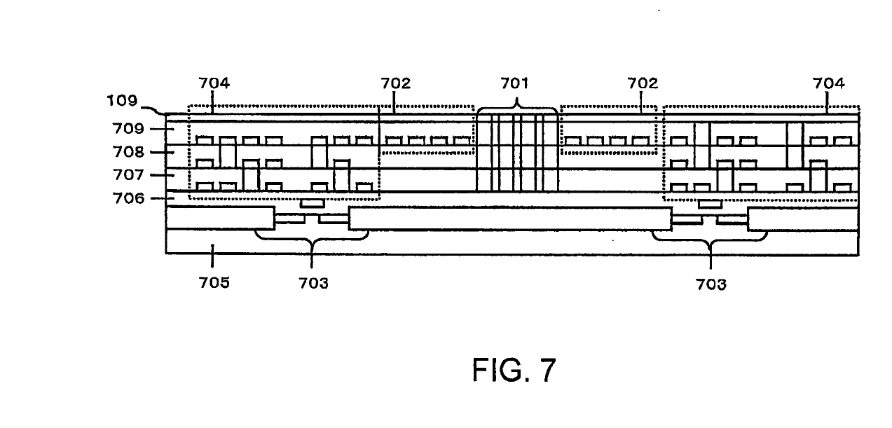

Next, a method of forming the three-dimensional semiconductor device according to the first embodiment of the present invention will be described with reference to FIGS. 7, 8 and 9.

As shown in FIG. 7, a first layer of two-dimensional LSI (703) is formed on a single crystal silicon substrate (705) by an LSI process. The two-dimensional LSI includes an insulated gate transistor including a source region, a drain region and a channel region, as shown in the drawing. With respect to each of wiring regions (707, 708 and 709) constituting the first layer of two-dimensional LSI, a multilayer wiring region (704) is made of an electrically-conductive material, and an inter-layer insulating film of the multilayer wiring region includes at least one kind of an oxide with a dielectric constant of less than 5, a nitride with a dielectric constant of less than 5, CFx (x<4) with a dielectric constant of 2.5 or less, CHx with a dielectric constant of 2.5 or less and a porous material with a dielectric constant of 2.5 or less.

In this regard, the multilayer wiring region 704 corresponds to the multilayer wiring region 105 in FIG. 1.

With respect to data bus penetration wiring (701), VIA contact holes are first formed by means of an etching process when the first layer of wiring region (707) is formed, and an electrically-conductive material is then deposited as well as formation of wiring. A material consisting of a metallic material or carbon is used as such an electrically-conductive material. Similarly, VIA contact holes are formed by means of an etching process when the second layer of wiring region (708) and the third layer of wiring region (709) are formed, and an electrically-conductive material is then deposited as well as formation of wiring. In this way, the data bus penetration wiring (701) can be formed. A method of forming the data bus penetration wiring with the formation process for each of the wiring regions (707, 708 and 709) has been described herein. However, there is no problem in a method of forming VIA contact holes of the three layers by means of an etching process after all wiring regions (707, 708 and 709) are formed and implanting an electrically-conductive material.

In this regard, 702 in FIG. 7 corresponds to the multilayer wiring region for connection of the data bus 104 in FIG. 1, and 706 in FIG. 7 is a region for connecting from the integrated circuits (703, 704) formed in the semiconductor layer to the multilayer wiring region 704 with wiring.

After the two-dimensional LSI is formed in this manner, an insulating layer (109) is formed on the upper surface to prepare a next step. This insulating layer (109) can use a material indicating a dielectric constant as explained with respect to the inter-layer insulating film of the multilayer wiring region.

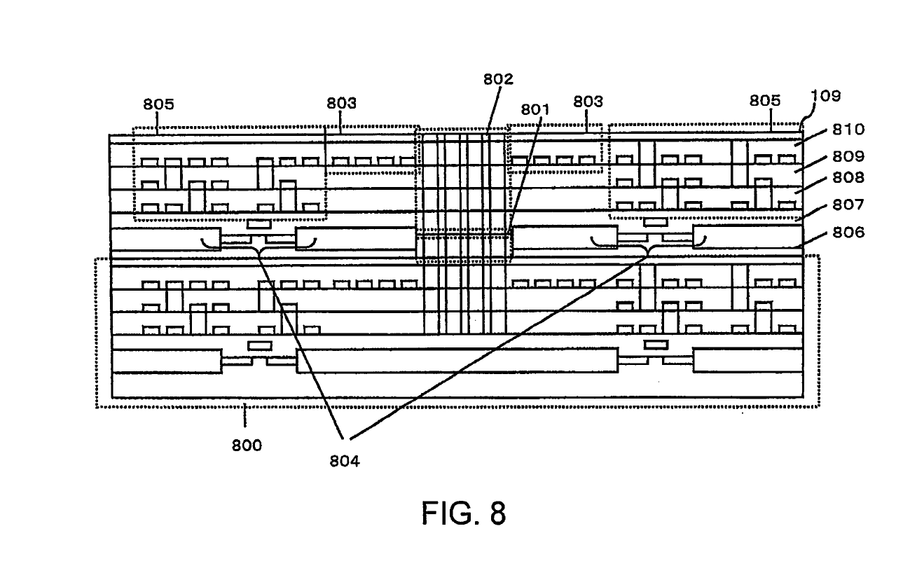

FIG. 8 shows a state in which a second layer of two-dimensional LSI is formed on the first layer of two-dimensional LSI shown in FIG. 7. As shown in FIG. 8, a single crystal or polycrystal silicon layer (806) is laminated on a first layer of two-dimensional LSI (800) that has been formed previously, and a second layer of two-dimensional LSI (804) is formed thereon. The two-dimensional LSI includes an insulated gate transistor including a source region, a drain region and a channel region, as shown in the drawing. Here, with respect to a penetration wiring region (801), an insulating film is laminated after subjecting the deposited single crystal or polycrystal silicon layer to etching; VIA contact holes are formed in a region for forming penetration wiring by means of an etching process; and an electrically-conductive material is then laminated as well as formation of wiring. With respect to each of wiring regions (808, 809 and 810) constituting the second layer of two-dimensional LSI, a multilayer wiring region (805) is made of an electrically-conductive material, and an inter-layer insulating film of the multilayer wiring region includes at least one kind of an oxide with a nitride of less than 5, a nitrogenous compound with a dielectric constant of less than 5, CFx (x<4) with a dielectric constant of 2.5 or less, CHx with a dielectric constant of 2.5 or less and a porous material with a dielectric constant of 2.5 or less.

With respect to data bus penetration wiring (802), VIA contact holes are first formed by means of an etching process when the first layer of wiring region (808) is formed, and an electrically-conductive material is then deposited as well as formation of wiring. Similarly, VIA contact holes are formed by means of an etching process when the second layer of wiring region (809) and the third layer of wiring region (810) are formed, and an electrically-conductive material is then deposited as well as formation of wiring. In this way, the data bus penetration wiring (802) can be formed. A method of forming the data bus penetration wiring with the formation process for each of the wiring regions (808, 809 and 810) has been described herein. However, there is no problem in a method of forming VIA contact holes of the three layers by means of an etching process after all wiring regions (808, 809 and 810) are formed and implanting an electrically-conductive material. In this regard, 803 in FIG. 8 corresponds to the multilayer wiring region for connection of the data bus in FIG. 1, and 807 in FIG. 8 is a region for connecting from the integrated circuit (804) formed in the semiconductor layer to the multilayer wiring region 805 with wiring.

After the second layer of two-dimensional LSI is formed in this manner, an insulating layer (109) is formed on the upper surface to prepare a next step.

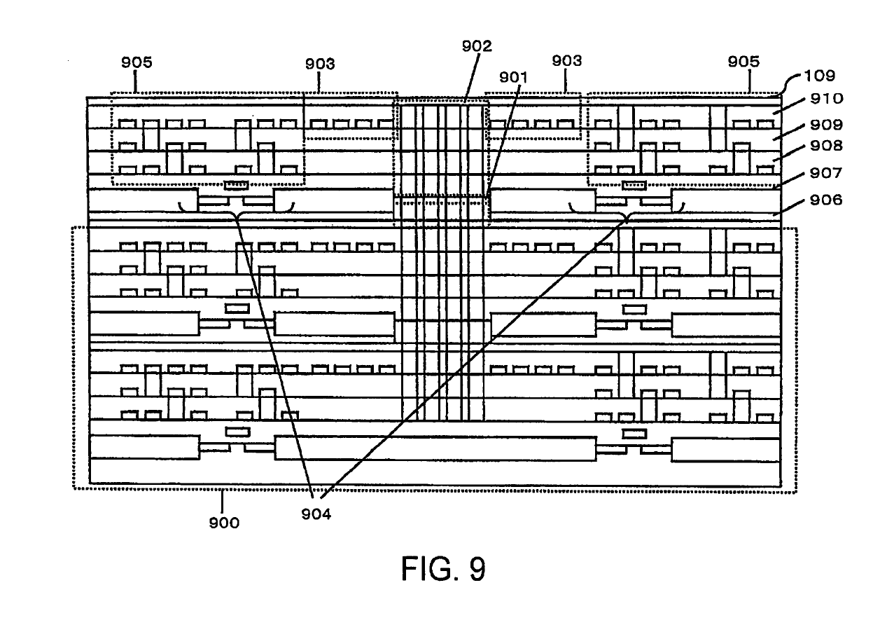

FIG. 9 shows a state in which a third layer of two-dimensional LSI is formed on the first and second layers of two-dimensional LSIs. The two-dimensional LSI includes an insulated gate transistor including a source region, a drain region and a channel region, as shown in the drawing. As shown in FIG. 9, a single crystal or polycrystal silicon layer (906) is laminated on the first and second layers of two-dimensional LSIs (900) that have been formed previously, and a third layer of two-dimensional LSI (904) is formed thereon. Here, with respect to a penetration wiring region (901), an insulating film is laminated after subjecting the laminated single crystal or polycrystal silicon layer to etching; VIA contact holes are formed in a region for forming penetration wiring by means of an etching process; and an electrically-conductive material is then laminated as well as formation of wiring. With respect to each of wiring regions (908, 909 and 910) constituting the third layer of two-dimensional LSI, a multilayer wiring region (905) is made of an electrically-conductive material, and an inter-layer insulating film of the multilayer wiring region includes at least one kind of an oxide with a dielectric constant of less than 5, a nitride with a dielectric constant of less than 5, CFx (x<4) with a dielectric constant of 2.5 or less, CHx with a dielectric constant of 2.5 or less and a porous material with a dielectric constant of 2.5 or less.

With respect to data bus penetration wiring (902), VIA contact holes are first formed by means of an etching process when the first layer of wiring region (908) is formed, and an electrically-conductive material is then deposited as well as formation of wiring. Similarly, VIA contact holes are formed by means of an etching process when the second layer of wiring region (909) and the third layer of wiring region (910) are formed, and an electrically-conductive material is then deposited as well as formation of wiring. In this way, the data bus penetration wiring (902) can be formed. A method of forming the data bus penetration wiring with the formation process for each of the wiring regions (908, 909 and 910) has been described therein. However, there is no problem in a method of forming VIA contact holes of the three layers by means of an etching process after all wiring regions (908, 909 and 910) are formed and implanting an electrically-conductive material.

Although the embodiments have been described in which the wiring regions of the respective semiconductor layers are the three layers of wiring regions, there is no limitation on the number of layers of the wiring regions and it is arbitrary. Further, although the embodiments have been described in which the number of semiconductor layers is three, there is no limitation on the number of semiconductor layers and it is arbitrary.

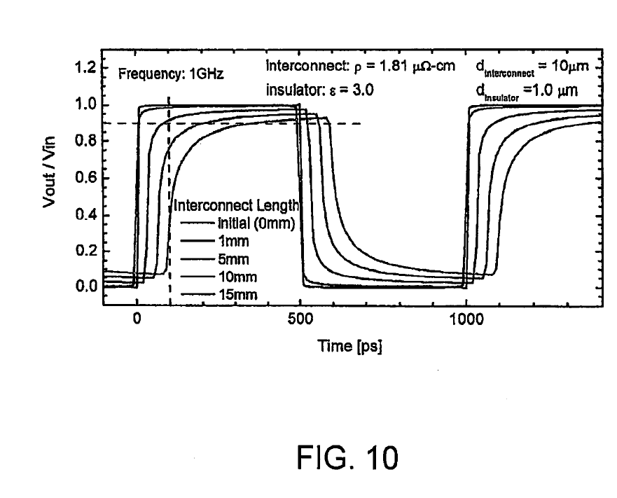

In the case where a system LSI with 10 square mm is formed using a conventional two-dimensional LSI structure, a data bus wiring length amounts to about 10 mm. The case where a clock of 1 GHz is applied to the data bus without inserting a repeater was checked. FIG. 10 shows its result in addition to the case of other data wiring length. Waveforms in the drawing correspond to bus wiring lengths of 0 mm, 1 mm, 5 mm, 10 mm and 15 mm in order of good rising edge. In the case the bus wiring length is 10 mm, it merely reaches voltage of 80% even after 100 psec in comparison with a rising clock, and it is difficult to propagate a clock signal of 1 GHz or higher without a repeater in the data bus wiring whose length is 5 mm or longer.

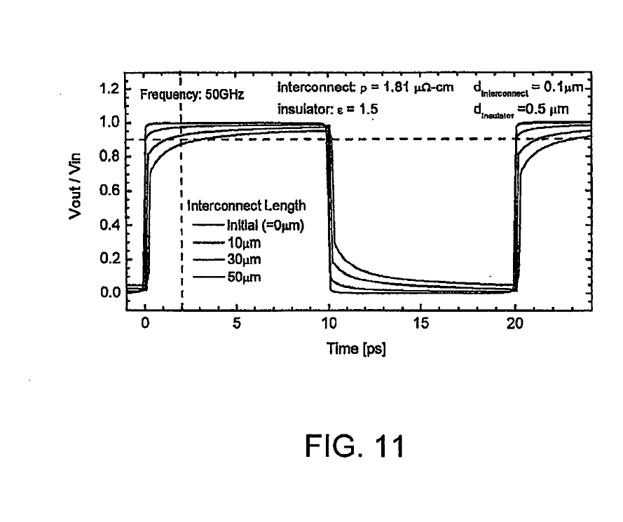

In the three-dimensional structural semiconductor device as shown in FIG. 9, the data bus penetration wiring is arranged in a laminated direction. For this reason, a wiring length becomes about 2 to 3 μm even though a wiring region for 10 layers per one semiconductor layer is formed. Therefore, even in the case where three semiconductor layers, for example, are formed, it can be thought that it is about 10 μm. In the case where the inter-layer insulating film is composed of at least one kind of CFx (x<4), CHx and porous materials with a low dielectric constant, it can be seen that even a clock of 50 GHz propagates without problems as shown in FIG. 11. In this regard, waveforms in FIG. 11 correspond to bus wiring lengths of 0 μm, 10 μm, 30 μm and 50 μm in order of good rising.

In this way, by arranging the data bus penetration wiring in the laminated direction, a high-speed operation becomes possible.

In this regard, in the case of a three-dimensional semiconductor device in which the number of lamination is increased, by arranging a buffer circuit on the way of the penetration wiring, speeding up can be realized even though the penetration wiring becomes long in the laminated direction.

In FIGS. 7 to 9 as described above, although the method of forming the three-dimensional structural semiconductor device according to the first embodiment has been described, it can be understood that the method can also be applied to the semiconductor device according to the second embodiment. Therefore, its explanation is omitted.

1. A three-dimensional structural semiconductor device, comprising:
a first integrated circuit constructed so as to include a plurality of regions formed in a first semiconductor layer and a first wiring layer formed on the first semiconductor layer;
a first insulating layer laminated on the first wiring layer; and
a second integrated circuit constructed so as to include a plurality of regions formed in a second semiconductor layer laminated on the first insulating layer and a second wiring layer formed on the second semiconductor layer,
wherein the first integrated circuit and the second integrated circuit are electrically connected by means of wiring penetrating in a laminated direction, and at least one of two-way data communication between the first integrated circuit and the second integrated circuit, supply of a control signal and supply of a clock signal is carried out via the penetrating wiring.

2. The three-dimensional structural semiconductor device as claimed in claim 1, wherein one or more layered structure in which an insulating layer, a semiconductor layer and a wiring layer are laminated on the second wiring layer in this order is formed; an integrated circuit including a plurality of regions formed in the semiconductor layer of the layered structure and a wiring layer of the layered structure is configured; the penetration wiring penetrates the semiconductor layer and the wiring layer of the layered structure in the laminated direction to be electrically connected to the integrated circuit in each group; and at least one of two-way data communication, control signal communication, and supply of a clock signal among the first integrated circuit, the second integrated circuit, and the integrated circuit of the layered structure is carried out via the penetration wiring.

3. The three-dimensional structural semiconductor device as claimed in claim 1, wherein the first wiring layer and the second wiring layer include a multilayer wiring layer.

4. The three-dimensional structural semiconductor device as claimed in claim 1, wherein the regions formed on the semiconductor layers include a source region, a drain region and a channel region of an insulated gate transistor.

5. The three-dimensional structural semiconductor device as claimed in claim 1, wherein any of the two-way data communication, the control signal communication, and the supply of a clock signal is adapted to be carried out via the penetrating wiring.

6. The three-dimensional structural semiconductor device as claimed in claim 1, wherein the penetration wiring is arranged on a central portion of the first semiconductor layer.

7. The three-dimensional structural semiconductor device as claimed in claim 1, wherein a buffer circuit is inserted on the way of the penetration wiring.

8. The three-dimensional structural semiconductor device as claimed in claim 1, wherein each of the first integrated circuit and the second integrated circuit includes one or more specific circuit.

9. The three-dimensional structural semiconductor device as claimed in claim 2, wherein each of the first integrated circuit, the second integrated circuit, and the integrated circuit of the layered structure includes a plurality of specific circuits.

10. The three-dimensional structural semiconductor device as claimed in claim 8, wherein the penetration wiring is electrically connected to each of the specific circuits via a bus interface.

11. The three-dimensional structural semiconductor device as claimed in claim 8, wherein the specific circuit is constructed from any one of a CPU, a memory, a dedicated hard logic and an external interface.

12. The three-dimensional structural semiconductor device as claimed in claim 1, wherein each of the first integrated circuit and the second integrated circuit is constructed from at least one of a digital circuit, an analog circuit, and a digital-analog mixed circuit.

13. The three-dimensional structural semiconductor device as claimed in claim 1, wherein in addition to the penetration wiring, the first wiring layer and the second wiring layer are connected by means of local bus wiring for carrying out two-way local data communication between the first integrated circuit and the second integrated circuit.

14. The three-dimensional structural semiconductor device as claimed in claim 1, wherein the penetration wiring is formed from at least one of materials composed of metallic materials and carbon.

15. The three-dimensional structural semiconductor device as claimed in claim 1, wherein the first insulating layer is formed from at least one of an oxide, a nitride and a carbon compound whose dielectric constant is less than five.

16. The three-dimensional structural semiconductor device as claimed in claim 1, wherein the first insulating layer is formed from at least one of CFx (x<4), CHx and a porous material whose dielectric constant is 2.5 or less.

17. A three-dimensional structural semiconductor device, comprising:
a first integrated circuit constructed so as to include a plurality of regions formed in a first semiconductor layer and a first wiring layer formed on the first semiconductor layer;
a first insulating layer laminated on the first wiring layer;
a second integrated circuit constructed so as to include a plurality of regions formed on a second semiconductor layer laminated on the first insulating layer and a second wiring layer formed on the second semiconductor layer; and
penetration bus wiring that penetrates the first semiconductor layer and the second semiconductor layer in a laminated direction to electrically connect the first integrated circuit to the second integrated circuit.

18. A method of manufacturing a three-dimensional structural semiconductor device, the method comprising:
forming a first integrated circuit constructed so as to include a plurality of regions formed in a first semiconductor layer and a first wiring layer formed on the first semiconductor layer;
forming a second integrated circuit constructed so as to include a plurality of regions formed on a second semiconductor layer laminated on a first insulating layer laminated on the first wiring layer, and a second wiring layer formed on the second semiconductor layer;
forming penetration wiring that penetrates the first semiconductor layer and the second semiconductor layer in a laminated direction; and
electrically connecting the first integrated circuit to the second integrated circuit by means of the penetration wiring.
